(19) United States
(12) Patent Application Publication
(10) Pub. No.: US 2022/0349745 A1
(43) Pub. Date: Nov. 3, 2022

(54) Vibration Sensor

(71) Applicant: AAC ACOUSTIC TECHNOLOGIES (SHENZHEN) CO., LTD., Shenzhen (CN)

(72) Inventors: Tingting Hong, Shenzhen (CN); Xingfu Chen, Shenzhen (CN)

(21) Appl. No.: 17/541,284

(22) Filed: Dec. 3, 2021

(30) Foreign Application Priority Data
Apr. 28, 2021 (CN) 202120908664.3

(51) Int. Cl. G01H 11/06; H04R 19/04

(52) U.S. Cl. CPC G01H 11/06; H04R 19/04; H04R 2201/003

(57) ABSTRACT

One of the main objects of the present invention is to provide a vibration sensor with improved sensitivity. To achieve the above-mentioned object, the present invention provides a vibration sensor including a circuit board assembly; a housing fixed to the circuit board assembly for forming an accommodation space cooperatively with the circuit board assembly; and a diaphragm assembly accommodated in the accommodation space and secured to the circuit board assembly. The diaphragm assembly includes a gasket fixed to the circuit board assembly, and a first diaphragm fixed to a side of the gasket away from the circuit board assembly. The sensor further includes a vibration cavity enclosed by the gasket, the first diaphragm, and the circuit board assembly, and a MEMS microphone accommodated in the vibration cavity and electrically connected to the circuit board assembly.

### FIELD OF THE PRESENT DISCLOSURE

The present invention relates to electromechanical transducers, and more particularly to vibration sensor for converting vibration to electrical signals.

### DESCRIPTION OF RELATED ART

With the development of technology, microphone equipment is evolving from traditional air conduction microphones to bone conduction microphones. Generally, the bone conduction microphone senses the bone vibration when the user utters through the diaphragm assembly, and then transmits it to the MEMS microphone by the diaphragm assembly. Finally, the MEMS microphone converts the vibration signal into an electrical signal for recording or transmission. However, the positions of the diaphragm assembly and the MEMS microphone in the bone conduction microphone of the prior art are unreasonable. As a result, the diaphragm assembly cannot effectively transmit the vibration signal to the MEMS microphone, which is prone to insensitivity.

Therefore, it is necessary to provide a new vibration sensor to solve the above problems.

### SUMMARY OF THE PRESENT INVENTION

One of the main objects of the present invention is to provide a vibration sensor with improved sensitivity.

To achieve the above-mentioned objects, the present invention provides a vibration sensor including a circuit board assembly; a housing fixed to the circuit board assembly for forming an accommodation space cooperatively with the circuit board assembly; and a diaphragm assembly accommodated in the accommodation space and secured to the circuit board assembly. The diaphragm assembly includes a gasket fixed to the circuit board assembly, and a first diaphragm fixed to a side of the gasket away from the circuit board assembly. The sensor further includes a vibration cavity enclosed by the gasket, the first diaphragm, and the circuit board assembly, and a MEMS microphone accommodated in the vibration cavity and electrically connected to the circuit board assembly.

In addition, the vibration sensor further includes an ASIC chip accommodated in the accommodation space and electrically connected to the circuit board assembly; wherein the gasket isolates the ASIC chip from the MEMS microphone.

In addition, the circuit board assembly includes an inner wire; the MEMS microphone includes a first gold wire; the ASIC chip includes a second gold wire; the inner wire is electrically connected to the first gold wire and the second gold wire.

In addition, the housing includes a side wall fixed to the circuit board assembly and a top wall fixed to the side wall away from the circuit board assembly; the housing is provided with at least one first vent hole penetrating therethrough.

In addition, the diaphragm assembly has at least one second vent hole penetrating therethrough; the vibration cavity communicates with the accommodation space through the at least one second vent hole.

In addition, the diaphragm assembly further includes a weight locating on a side of the first diaphragm close to the circuit board assembly and/or a side of the first diaphragm away from the circuit board assembly.

In addition, the MEMS microphone includes a substrate fixed to the circuit board assembly, a second diaphragm and a back plate respectively fixed to the substrate on a side away from the circuit board assembly; the second diaphragm, the back plate and the first diaphragm are sequentially arranged at intervals.

In addition, the MEMS microphone separates the vibration cavity into a front cavity located between the diaphragm assembly and the MEMS microphone, and a back cavity located inside the MEMS microphone and having a greater volume than the front cavity.

### BRIEF DESCRIPTION OF THE DRAWINGS

Many aspects of the exemplary embodiment can be better understood with reference to the following drawings. The components in the drawing are not necessarily drawn to scale, the emphasis instead being placed upon clearly illustrating the principles of the present disclosure.

FIG. 1 is a cross-sectional view of a vibration sensor in accordance with an exemplary embodiment of the present invention.

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

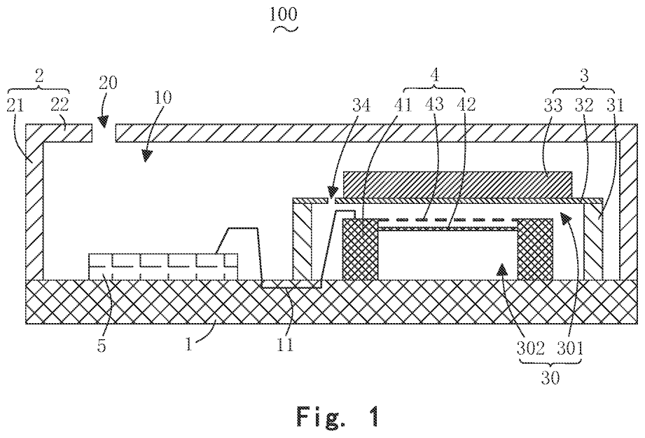

Please refer to FIG. 1. This present invention provides a vibration sensor 100, which includes a circuit board assembly 1, a housing 2, a diaphragm assembly 3, an MEMS microphone 4, and an ASIC chip 5.

Specifically, the housing 2 includes a side wall 21 fixed to the circuit board assembly 1 and a top wall 22 fixed to the side wall 21 away from the circuit board assembly 1. The circuit board assembly 1, the side wall 21 and the top wall 22 are enclosed to form the accommodation space 10. The diaphragm assembly 3, the MEMS microphone 4 and ASIC chip 5 are all accommodated in the accommodation space 10 and fixed on the circuit board assembly 1 respectively. Both the MEMS microphone 4 and the ASIC chip 5 are electrically connected to the circuit board assembly 1. And the circuit board assembly 1 includes an inner wire 11 provided thereon. MEMS microphone 4 is provided with a first gold wire 40, ASIC chip 5 is provided with a second gold wire 50, the inner wire 11 is electrically connected to the first gold wire 40 and the second gold wire 50 at the same time.

In this embodiment, a first vent hole 20 is provided on the top wall 22, and the first vent hole 20 is arranged to balance the internal and external air pressure of the vibration sensor 100. Specifically, the accommodation space 10 communicates with the outside through the first vent hole 20. When housing 2 is assembled on circuit board assembly 1, excess gas can be discharged through first vent hole 20. This effectively avoids the formation of high pressure in the accommodation space 10 during the assembly process. It should be noted that, in other embodiments, the specific number and specific positions of the first vent hole 20 are not limited to those shown in FIG. 1. The actual implementation can be adjusted according to needs.

The diaphragm assembly 3 includes a gasket 31 fixed on the circuit board assembly 1, a first diaphragm 32 fixed on the side of the gasket 31 away from the circuit board assembly 1, and a weight 33 fixed on the side of the first diaphragm 32 away from the circuit board assembly 1. The circuit board assembly 1, the gasoline 31, and the first diaphragm 32 are enclosed to form a vibration cavity 30. The MEMS microphone 4 is arranged in the vibration cavity 30 and is arranged apart from the diaphragm assembly 3. The MEMS microphone 4 is accommodated in the vibration cavity 30 so that the diaphragm assembly 3 and the MEMS microphone 4 are closer to each other. The vibration of the diaphragm assembly 3 can be transmitted to the MEMS microphone 4 more effectively, thereby improving the sensitivity of the vibration sensor 100. In addition, the gasket 31 separates the MEMS microphone 4 from the ASIC chip 5, which improves the reliability of the vibration sensor 100.

The weight 33 increases the inertia of diaphragm assembly 3, thereby increasing the sensitivity of diaphragm assembly 3. It should be noted that in other embodiments, the weight 33 can also be set in other positions of the first diaphragm 32, or set in the first diaphragm 32 in other forms.

In this embodiment, a second vent hole 34 is provided on the first diaphragm 32, and the setting of the second vent hole 34 can balance the internal and external air pressure of the vibration cavity 30. Specifically, the vibration cavity 30 is connected to the accommodation space 10 through the second vent hole 34. When the diaphragm assembly 3 vibrates, the gas in the vibration cavity 30 and the accommodation space 10 can flow through the second vent hole 34. The air pressure in the vibration cavity 30 and the accommodation space 10 is balanced, and the accommodation space 10 and the vibration cavity 30 on both sides of the diaphragm assembly 3 are prevented from forming a closed space. When the diaphragm assembly 3 is caused to vibrate, high pressure or low pressure is formed in the accommodation space 10 and the vibration cavity 30 to affect the vibration amplitude of the diaphragm assembly 3. Thereby affecting the sensitivity of the vibration sensor 100. It should be noted that, in other embodiments, the specific number and specific positions of the second vent hole 34 are not limited to those shown in FIG. 1. The actual implementation can be adjusted according to needs.

The MEMS microphone 4 includes a substrate 41 fixed to the circuit board assembly 1, a second diaphragm 42 and a back plate 43 respectively fixed to the substrate 41 on the side away from the circuit board assembly 1. The second diaphragm 42, the back plate 43, and the first diaphragm 32 are sequentially arranged at intervals. The substrate 41 and the back plate 43 divide the vibration cavity 30 into a front cavity 301 and a back cavity 302. The front cavity 301 is located between the diaphragm assembly 3 and the MEMS microphone 4. The back cavity 302 is located inside the MEMS microphone 4.

When the vibration sensor 100 receives a vibration signal or a pressure signal, the diaphragm assembly 3 vibrates. Specifically, the weight 33 vibration drives the first diaphragm 32 to vibrate, so that the gas in the vibration cavity 30 vibrates. As a result, the second diaphragm 42 of the MEMS microphone 4 located in the vibration cavity 30 vibrates. The distance between the second diaphragm 42 and the back plate 43 changes during the vibration process, that is, the capacitance generated by the MEMS microphone 4 is changed. In this way, the vibration signal or pressure signal is converted into a corresponding electrical signal.

Moreover, in this embodiment, the MEMS microphone 4 is arranged in the vibration cavity 30 and is arranged at a distance from the diaphragm assembly 3. The small size of the front cavity 301 enables the vibration of the weight 33 to be transmitted to the second diaphragm 42 more effectively. Thereby improving the sensitivity of the vibration sensor 100.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A vibration sensor including:
a circuit board assembly;
a housing fixed to the circuit board assembly for forming an accommodation space cooperatively with the circuit board assembly;
a diaphragm assembly accommodated in the accommodation space and secured to the circuit board assembly, including a gasket fixed to the circuit board assembly, and a first diaphragm fixed to a side of the gasket away from the circuit board assembly;
a vibration cavity enclosed by the gasket, the first diaphragm, and the circuit board assembly; and
a MEMS microphone accommodated in the vibration cavity and electrically connected to the circuit board assembly.

2. The vibration sensor as described in claim 1, further including an ASIC chip accommodated in the accommodation space and electrically connected to the circuit board assembly; wherein the gasket isolates the ASIC chip from the MEMS microphone.

3. The vibration sensor as described in claim 2, wherein, the circuit board assembly includes an inner wire; the MEMS microphone includes a first gold wire; the ASIC chip includes a second gold wire; the inner wire is electrically connected to the first gold wire and the second gold wire.

4. The vibration sensor as described in claim 1, wherein, the housing includes a side wall fixed to the circuit board assembly and a top wall fixed to the side wall away from the circuit board assembly; the housing is provided with at least one first vent hole penetrating therethrough.

5. The vibration sensor as described in claim 4, wherein, the diaphragm assembly has at least one second vent hole penetrating therethrough; the vibration cavity communicates with the accommodation space through the at least one second vent hole.

6. The vibration sensor as described in claim 5, wherein, the diaphragm assembly further includes a weight locating on a side of the first diaphragm close to the circuit board assembly and/or a side of the first diaphragm away from the circuit board assembly.

7. The vibration sensor as described in claim 1, wherein, the MEMS microphone includes a substrate fixed to the circuit board assembly, a second diaphragm and a back plate respectively fixed to the substrate on a side away from the circuit board assembly; the second diaphragm, the back plate and the first diaphragm are sequentially arranged at intervals.

8. The vibration sensor as described in claim 7, wherein, the MEMS microphone separates the vibration cavity into a front cavity located between the diaphragm assembly and the MEMS microphone, and a back cavity located inside the MEMS microphone and having a greater volume than the front cavity.
